(19) United States
(12) Patent Application Publication
(10) Pub. No.: US 2023/0319974 A1
(43) Pub. Date: Oct. 5, 2023

(54) DETACHABLE HEAT SINK

(71) Applicant: LIPOWER NEW ENERGY TECHNOLOGY CO.,LTD, Shenzhen (CN)

(72) Inventor: Zhiyu Yu, Shenzhen (CN)

(21) Appl. No.: 17/709,760

(22) Filed: Mar. 31, 2022

(51) Int. Cl. H05K 1/02; H05K 7/20

(52) U.S. Cl. CPC H05K 1/0203; H05K 7/20336; H05K 7/20136; H05K 7/2039

(57) ABSTRACT

The invention relates to a detachable and separated heat dissipation device, which is characterized by comprising a PCBA circuit board, a metal pressure lock, a metal heat-conducting support, a heat-pipe heat-dissipating module and a convection fan, and one side of the metal heat-conducting support is provided with an insulating heat-conducting pad, the metal heat-conducting bracket is arranged on the PCBA circuit board, the metal heat-conducting bracket is provided with an installation slot, and the heat pipe extension of the heat pipe cooling module is inserted into the preset installation slot of the metal heat-conducting bracket, the PCBA The electronic heating elements arranged in a row on the circuit board are fixed on the insulating and heat-conducting pad of the metal heat-conducting support through screws. The advantages of the present invention are that the working efficiency of electronic components can be improved to meet this demand and provide better temperature rise redundancy.

### TECHNICAL FIELD

The invention relates to the technical field of heat dissipation of electronic heating components, in particular to a detachable and separated heat dissipation device.

### BACKGROUND

The working efficiency and service life of power devices such as triodes and bridge rectifiers have higher requirements on temperature control, and metal profiles are usually used to dissipate heat with fans. However, as the output load gradually increases, such common cooling devices cannot meet the system requirements.

### SUMMARY OF THE INVENTION

The technical problem to be solved by the present invention is to solve the above problems, and to provide a brand new detachable and separated heat dissipation device that can meet this demand and can effectively lower temperature rise redundancy.

In order to solve the above technical problems, the technical solution is provided by the present invention: a detachable and separated heat dissipation device, comprising PCBA circuit boards, metal heat conduction brackets, metal pressure locks, heat pipe radiator modules and convection fans. One side of the metal heat conduction brackets are equipped with insulating thermal pads. The brackets with mounting slots is arranged on the PCBA circuit board. The extensions of the heat pipe radiator modules are inserted into the mounting slots of the brackets. The heat pipes are fastened to the mounting slots of the bracket by locking the metal pressure lock. The heat exchange fins of the heat pipe cooling module are as large as possible. The components are fixed on the metal heat-conducting bracket by screws.

Further, the metal heat-conducting supports are set to at least two groups, the number of the convection fans is the same as that of the metal heat-conducting supports, and the corresponding metal heat-conducting supports are set.

After the above structure is adopted, the present invention has the following advantages: the product of the present invention can efficiently conduct heat from the electronic heating components to the heat exchange fins of the heat pipe cooling module; compared with the traditional profile heat dissipation structure, it can greatly reduce the electronic heating The temperature of the components can improve the working efficiency of the components. At the same time, the large-area heat exchange fins improve the heat exchange efficiency of the air, which can reduce the noise pollution generated by the high-speed fan in the traditional profile heat dissipation structure.

### BRIEF DESCRIPTION OF THE DRAWINGS

FIG. 1 is a schematic view of the front structure of a detachable and separated heat sink according to the present invention.

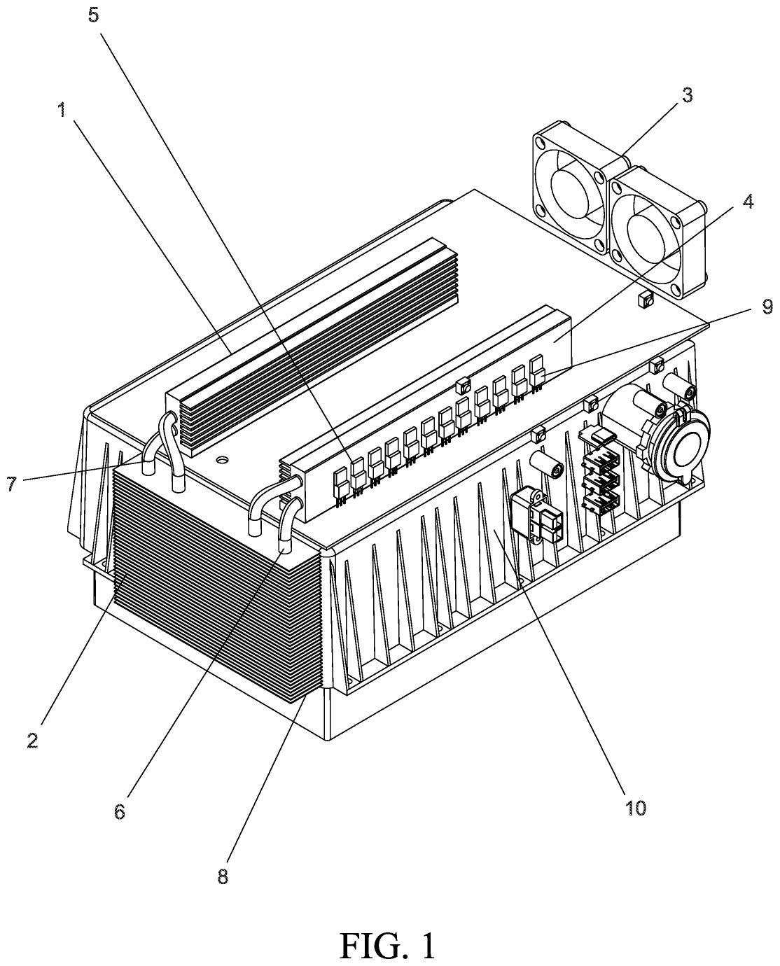

FIG. 2 is a schematic structural diagram of a detachable and separated heat dissipation device of the present invention installed on a product in use.

As shown in the picture: 1. Metal heat-conducting bracket, 2. Metal pressure lock, 3. Heat pipe cooling module, 4. Convection fan, 5. Insulating heat-conducting pad, 6. PCBA circuit board, 7. Mounting slot, 8. Heat pipes, 9, heat exchange fins, 10, electronic heating components.

### DETAILED DESCRIPTION

The present invention will be further described in detail below in conjunction with the accompanying drawings.

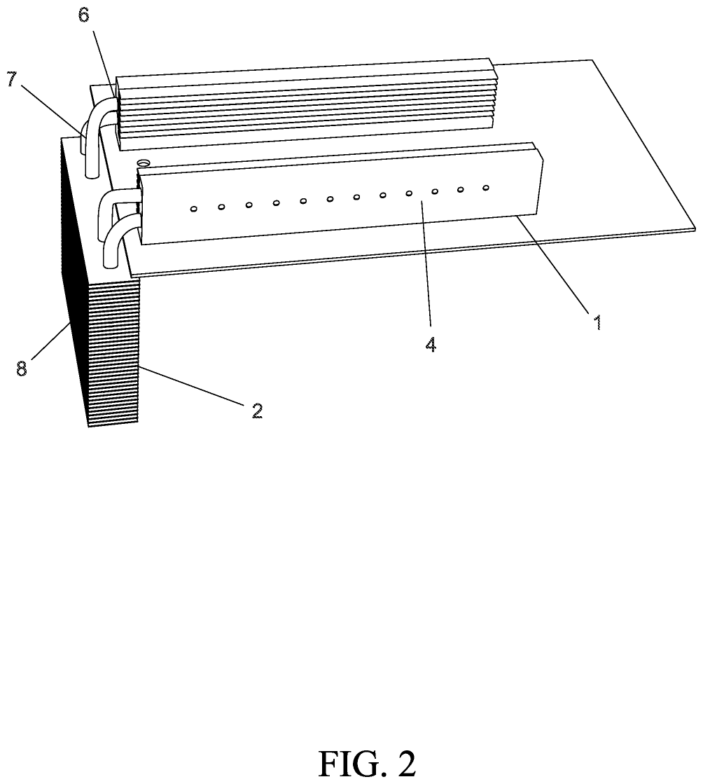

1 and 2, a detachable and separate heat dissipation device includes a PCBA circuit board 6, a metal heat-conducting support 1, a heat pipe cooling module 3 and a convection fan 4. The heat pipe cooling module 3 can use commonly used heat pipes on the market. A radiator or a similar heat dissipation structure, one side of the metal heat-conducting support 1 is provided with an insulating heat-conducting pad 5, the metal heat-conducting support 1 is arranged on the PCBA circuit board 6, and the PCBA circuit board 5 is installed on the device to be installed (As shown in FIG. 2), the metal heat-conducting bracket 1 is provided with an installation slot 7, and the extension of the heat pipe 8 of the heat-pipe cooling module 2 is inserted into the preset installation slot 7 of the metal heat-conducting bracket 1. The metal pressure lock 2 fastens the heat pipe 8 in the installation hole 7 of the metal heat conduction bracket 1 with the fixing screw of the heat pipe 8, and the heat exchange fins 9 of the heat pipe cooling module 3 are as large as possible. The electronic heating components 10 arranged in rows are fixed on the metal heat-conducting support 1 by screws.

Further, the metal heat-conducting brackets 1 are set to at least two groups, the number of the convection fans 4 is the same as that of the metal heat-conducting brackets 1, and is set corresponding to the metal heat-conducting brackets 1, and the convection fans are installed on the inner side of the electronic component installation shell that needs to be dissipated, and the inside of the electronic component mounting case should have a vent that can supply air in and out of the convection fan.

During the specific implementation of the present invention, the product of the present invention can efficiently conduct heat from the electronic heating components to the heat exchange fins of the heat pipe cooling module; Improve the working efficiency of components, and at the same time, due to the large area of heat exchange fins, the heat exchange efficiency of the air can be improved, which can reduce the noise pollution caused by the high-speed fan in the traditional profile heat dissipation structure; the electronic heating components can be completed first during production and assembly. The metal heat-conducting bracket is welded through the furnace, and then the installation and fixing of the heat pipe cooling module under the furnace surface is completed, which is simple, convenient and easy to promote.

The present invention and its embodiments have been described above, and the description is not limiting, and the actual structure is not limited thereto. All in all, if those of ordinary skill in the art are inspired by it, and without departing from the purpose of the present invention, any structural modes and embodiments similar to this technical solution are designed without creativity, and all should belong to the protection scope of the present invention.

I claim:

1. A detachable heat dissipation device, characterized in that: comprising a PCBA circuit board, a metal heat-conducting support, a metal pressure lock, a heat pipe cooling module and a convection fan, and one side of the metal heat-conducting support is provided with an insulating heat-conducting pad, The metal heat-conducting bracket is arranged on the PCBA circuit board, the metal heat-conducting bracket is provided with an installation slot, and the heat pipe extension of the heat pipe cooling module is inserted into the preset installation slot of the metal heat-conducting bracket, and the PCBA circuit The electronic heating elements arranged in a row on the board are fixed on the insulating heat-conducting pad of the metal heat-conducting support by screws.

2. The detachable and separated heat dissipation device according to claim 1, wherein at least two groups of the metal heat-conducting brackets are arranged, and the number of the convection fans is the same as that of the metal heat-conducting brackets, and is arranged corresponding to the metal heat-conducting brackets.
